(19) United States
(12) Patent Application Publication
(10) Pub. No.: US 2011/0168248 A1
(43) Pub. Date: Jul. 14, 2011

(54) USE OF DIBENZOTETRAPHENYLPERIFLANTHENE IN ORGANIC SOLAR CELLS

(75) Inventors: Martin Koenemann, Mannheim (DE); Jae Hyung Hwang, Mannheim (DE); Gabriele Mattern, Schifferstadt (DE); Christian Doerr, Niederkirchen (DE); Peter Erk, Frankenthal (DE)

(73) Assignee: BASF SE, Ludwigshafen (DE)

(21) Appl. No.: 13/119,192

(22) PCT Filed: Sep. 18, 2009
(86) PCT No.: PCT/EP2009/062104

§ 371 Date: Mar. 16, 2011

(30) Foreign Application Priority Data
Sep. 19, 2008 (EP) 08164738.0

(51) Int. Cl. H01L 51/44; H01L 51/40; H01L 31/06

(52) U.S. Cl. 136/255; 438/82; 257/E51.012

(57) ABSTRACT

The present invention relates to the use of dibenzotetraphenylperiflanthene as an electron donor material in an organic solar cell.

### STATE OF THE ART

The present invention relates to the use of dibenzotetraphenylperiflanthene as an electron donor material in an organic solar cell.

The synthesis of dibenzotetraphenylperiflanthene is described by J. D. Debad, J. C. Morris, V. Lynch, P. Magnus and A. J. Bard in J. Am. Chem. Soc. 1996, 118, pages 2374-2379.

Owing to diminishing fossil raw materials and the CO₂ which is formed in the combustion of these raw materials and is active as a greenhouse gas, direct energy generation from sunlight is playing an increasing role. “Photovoltaics” is understood to mean the direct conversion of radiative energy, principally solar energy, to electrical energy. In solar cells, as in any voltage source, the voltage is at its highest in an open circuit, i.e. when the current is zero. The more current is taken, the lower the voltage will be, and it attains the value of 0 in a short circuit. Neither in an open circuit nor in a short circuit does the solar cell release any power. Between an open circuit and a short circuit there exists a point on the characteristic (current as a function of voltage) of the solar cell at which the power released is at its maximum (mpp, maximum power point). A solar cell is generally characterized with the aid of three parameters: the open-circuit voltage V_{OC}, the short-circuit current I_{SC} and the fill factor FF (FF=(Vₘₚₚ Iₘₚₚ/V_{OC} I_{SC})). Additionally of interest are the internal and external quantum efficiencies. The internal quantum efficiency is the ratio of the number of charge carriers extracted at the contacts to the number of photons absorbed. The external quantum efficiency is the ratio of the number of charge carriers extracted at the contacts to the number of incident photons. The efficiency (η) of a solar cell is calculated from the ratio of the maximum photovoltaically generated power to the corresponding incident light power (P_{light}):

η=(VₘₚₚIₘₚₚ/P_{light})=FFV_{OC}I_{SC}/P_{light}

The demonstration of the first organic solar cell with an efficiency in the percent range by Tang et al. in 1986 (C W. Tang et al., Appl. Phys. Lett. 48, 183 (1986)) was the starting point of intensive further development. Organic solar cells consist of a sequence of thin layers which typically have a thickness between 1 nm and 1 μm, and which consist at least partly of organic materials which are preferably applied by vapor deposition under reduced pressure or applied from a solution. The electrical contact connection is generally effected by means of metal layers and/or transparent conductive oxides (TCOs).

In contrast to inorganic solar cells, the light does not directly generate free charge carriers in organic solar cells, but rather excitons are formed first, i.e. electrically neutral excited states in the form of electron-hole pairs. These excitons can be separated only by very high electrical fields or at suitable interfaces. In organic solar cells, sufficiently high fields are unavailable, and so all existing concepts for organic solar cells are based on exciton separation at photoactive interfaces (organic donor-acceptor interfaces or interfaces to an inorganic semiconductor). For this purpose, it is necessary that excitons which have been generated in the volume of the organic material can diffuse to this photoactive interface.

The diffusion of excitons to the active interface thus plays a critical role in organic solar cells. In order to make a contribution to the photocurrent, the exciton diffusion length in a good organic solar cell must at least be in the order of magnitude of the typical penetration depth of light, in order that the predominant portion of the light can be utilized. Organic crystals or thin layers which are perfect in terms of structure and with regard to chemical purity do indeed satisfy this criterion. For large-area applications, however, the use of high-purity, monocrystalline organic materials is impossible and the production of multiple layers with sufficient structural perfection is still very difficult to date.

There has been no lack of attempts to improve the efficiency of organic solar cells. Some approaches to the achievement or improvement of the properties of organic solar cells are listed below:
One of the contact metals used has a large work function and the other a small work function, such that a Schottky barrier is formed by the organic layer.
One layer comprises two or more types of organic pigments which possess different spectral characteristics.
Various dopants serve, inter alia, to improve the transport properties.
Arrangement of a plurality of individual solar cells so as to form a so-called tandem cell which can be improved further, for example, by using p-i-n structures with doped transport layers of large band gap.

Instead of increasing the exciton diffusion length, it is alternatively also possible to reduce the mean distance to the next interface. To this end, it is possible to use mixed layers composed of donors and acceptors which form an interpenetrating network in which internal donor-acceptor heterojunctions are possible. Organic solar cells with photoactive donor-acceptor transitions in the form of a bulk heterojunction are described, for example, by G. Yu, J. Gao, J. C. Hummelen, F. Wudl, A. J. Heeger in Science, vol. 270, December 1995, pages 1789-1791.

The advantage of such a mixed layer is that the excitons generated only have to cover a very short distance before they arrive at a domain boundary where they are separated. Since the materials are in contact with one another everywhere in the mixed layer, it is crucial in this concept that the separated charges possess a long lifetime on the particular material and continuous percolation pathways for both kinds of charge carrier to the particular contact are present from every location. With this approach, it has been possible to achieve efficiencies of up to 2.5% (S. E. Shaheen et al. Appl. Phys. Lett., vol. 78, No. 6, pages 841-843).

In spite of the above-described advantages, a critical factor for the bulk heterojunction (BHJ) is to find suitable materials and production processes which lead to mixed layers which have continuous transport pathways for both electrons and holes to their particular contacts. Since the individual materials each make up only a portion of the mixed layer, the transport properties for the charge carriers additionally in many cases deteriorate significantly compared to the pure layers. In addition, there are substance classes, for example particular oligothiophenes, which are surprisingly completely unsuitable for use in BHJ cells. One possible cause might be that these molecules mix too well with the second semiconductor material used to produce the mixed layer and therefore do not form any percolation pathways. However, there is currently still no demonstrable explanation. It is therefore virtually unforeseeable whether a particular electron or hole conductor material is suitable at all, and certainly not whether it is advantageously suitable for use in an organic solar cell with photoactive donor-acceptor transitions in the form of a bulk heterojunction.

JP 2008-135540 describes the use of perylene derivatives of the general formula

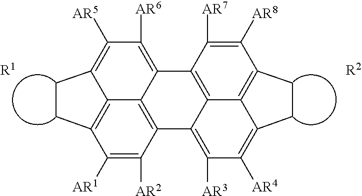

where R¹ and R² are each fused rings which may be substituted by alkyl, alkenyl, aryl, aralkyl or heterocyclyl, and AR¹-AR⁸ may each be alkyl, alkenyl, aryl, aralkyl or heterocyclyl, as an electron donor material for producing organic solar cells. Also mentioned is dibenzotetraphenylperiflanthene. However, this document does not teach the use of this compound for producing an organic solar cell with photoactive donor-acceptor transitions in the form of a bulk heterojunction.

It is an object of the invention to provide an organic solar cell in which the efficiency of energy conversion is improved.

It has now been found that, surprisingly, dibenzotetraphenylperiflanthene is particularly advantageously suitable as an electron donor material for producing organic solar cells with photoactive donor-acceptor transitions in the form of a bulk heterojunction.

### SUMMARY OF THE INVENTION

The invention therefore firstly provides for the use of dibenzotetraphenylperiflanthene (DBP) of the formula

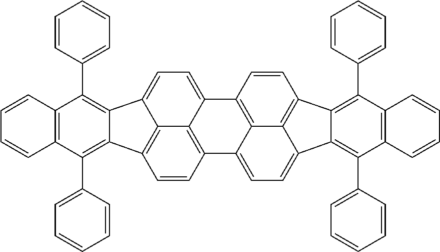

as an electron donor material in an organic solar cell with photoactive donor-acceptor transitions in the form of a bulk heterojunction.

The invention further provides an organic solar cell which comprises at least one photoactive donor-acceptor transition in the form of a bulk heterojunction, wherein dibenzotetraphenylperiflanthene is used as an electron donor material.

### DESCRIPTION OF FIGURES

FIG. 1 shows a solar cell which is suitable for the use of dibenzotetraphenyl-periflanthene and has a normal structure.

FIG. 2 shows a solar cell with inverse structure.

FIG. 3 shows the structure of a tandem cell.

FIG. 4 shows a bulk heterojunction with a large donor-acceptor interface and uninterrupted transport pathways to the electrodes.

### DESCRIPTION OF THE INVENTION

Organic solar cells generally have a layered structure and generally comprise at least the following layers: anode, photoactive layer and cathode. It is an essential feature of the invention that the organic solar cell has a mixed layer which comprises dibenzotetraphenylperiflanthene as an electron donor material and at least one electron acceptor material. According to the invention, the mixed layer has donor-acceptor transitions in the form of a bulk heterojunction.

Dibenzotetraphenylperiflanthene is prepared by customary methods known to those skilled in the art (e.g. J. D. Debad, J. C. Morris, V. Lynch, P. Magnus and A. J. Bard in J. Am. Chem. Soc. 1996, 118, pages 2374-2379).

Before use in an organic solar cell, the dibenzotetraphenylperiflanthene can be subjected to purification. The purification can be effected by customary methods known to those skilled in the art, such as separation on suitable stationary phases, sublimation, extraction, distillation, recrystallization or a combination of at least two of these measures. Each purification may have a one-stage or multistage configuration.

In a specific embodiment, the purification comprises a column chromatography method. To this end, the starting material present in a solvent or solvent mixture can be subjected to a separation or filtration on silica gel. Finally, the solvent is removed, for example by evaporation under reduced pressure. Suitable solvents are aromatics such as benzene, toluene, xylene, mesitylene, chlorobenzene or dichlorobenzene, hydrocarbons and hydrocarbon mixtures, such as pentane, hexane, ligroin and petroleum ether, halogenated hydrocarbons such as chloroform or dichloromethane, and mixtures of the solvents mentioned. For chromatography, it is also possible to use a gradient of at least two different solvents, for example a toluene/petroleum ether gradient.

In a further specific embodiment, the purification comprises a sublimation. This may preferably be a fractional sublimation. For fractional sublimation, it is possible to use a temperature gradient in the sublimation and/or the deposition of the dibenzotetraphenylperiflanthene. In addition, the purification can be effected by sublimation with the aid of a carrier gas stream. Suitable carrier gases are inert gases, for example nitrogen, argon or helium. The gas stream laden with the compound can subsequently be passed into a separating chamber. Suitable separating chambers may have a plurality of separation zones which can be operated at different temperatures. Preference is given, for example, to a so-called three-zone sublimation apparatus. A further process and an apparatus for fractional sublimation are described in U.S. Pat. No. 4,036,594.

An inventive organic solar cell typically comprises a substrate. The substrate is in many cases coated with a transparent, conductive layer as an electrode.

Suitable substrates for organic solar cells are, for example, oxidic materials (such as glass, ceramic, SiO₂, quartz, etc.), polymers (e.g. polyethylene terephthalate, polyolefins such as polyethylene and polypropylene, polyesters, fluoropolymers, polyamides, polyurethanes, polyalkyl (meth)acrylates, polystyrene, polyvinyl chloride and mixtures and composites thereof) and combinations thereof.

Suitable electrodes (cathode, anode) are in principle metals (preferably of groups 2, 8, 9, 10, 11 or 13 of the periodic table, e.g. Pt, Au, Ag, Cu, Al, In, Mg, Ca), semiconductors (e.g. doped Si, doped Ge, indium tin oxide (ITO), fluorinated tin oxide (FTO), gallium indium tin oxide (GITO), zinc indium tin oxide (ZITO), etc.), metal alloys (for example based on Pt, Au, Ag, Cu, etc., especially Mg/Ag alloys), semiconductor alloys, etc.

The material used for the electrode facing the light (the anode in a normal structure, the cathode in an inverse structure) is preferably a material at least partly transparent to the incident light. This includes especially glass and transparent polymers, such as polyethylene terephthalate. The electrical contact connection is generally effected by means of metal layers and/or transparent conductive oxides (TCOs). These preferably include ITO, FTO, ZnO, TiO₂, Ag, Au, Pt.

The layer facing the light is configured such that it is sufficiently thin to bring about only minimal light absorption but thick enough to enable good charge transport of the extracted charge carriers. The thickness of the layer is preferably within a range from 20 to 200 nm.

In a specific embodiment, the material used for the electrode facing away from the light (the cathode in a normal structure, the anode in an inverse structure) is a material which at least partly reflects the incident light. This includes metal films, preferably of Ag, Au, Al, Ca, Mg, In, and mixtures thereof. The thickness of the layer is preferably within a range from 50 to 300 nm.

The photoactive layer comprises, as an electron donor material (p-semiconductor), dibenzotetraphenylperiflanthene. In a specific embodiment, dibenzotetraphenylperiflanthene is used as the sole electron donor material.

According to the invention, the photoactive layer is configured as a mixed layer and comprises, in addition to DBP, at least one electron acceptor material (n-semiconductor).

For combination with DBP (donor), the following semiconductor materials are suitable in principle as acceptors for use in the inventive solar cells:

Fullerenes and fullerene derivatives, preferably selected from C₆₀, C₇₀, C₈₄, phenyl-C₆₁-butyric acid methyl ester ([60]PCBM), phenyl-C₇₁-butyric acid methyl ester ([71]PCBM), phenyl-C₈₂-butyric acid methyl ester ([84]PCBM), phenyl-C₆₁-butyric acid butyl ester ([60]PCBB), phenyl-C₆₁-butyric acid octyl ester ([60]PCBO), thienyl-C₆₁-butyric acid methyl ester ([60]ThCBM) and mixtures thereof. Particular preference is given to C₆₀, [60]PCBM and mixtures thereof.

Phthalocyanines which, for example owing to their substitution, are suitable as acceptors. These include hexadecachlorophthalocyanines and hexadecafluorophthalocyanines, such as copper hexadecachlorophthalocyanine, zinc hexadecachlorophthalocyanine, metal-free hexadecachlorophthalocyanine, copper hexadecafluorophthalocyanine, zinc hexadecafluorophthalocyanine or metal-free hexadecafluorophthalocyanine.

Rylenes, i.e. generally compounds with a molecular structure of naphthalene units bonded in the peri position. According to the number of naphthalene units, they may, for example, be perylenes (m=2), terrylenes (m=3), quaterrylenes (m=4) or higher rylenes. They may accordingly be perylenes, terrylenes or quaterrylenes of the following formulae

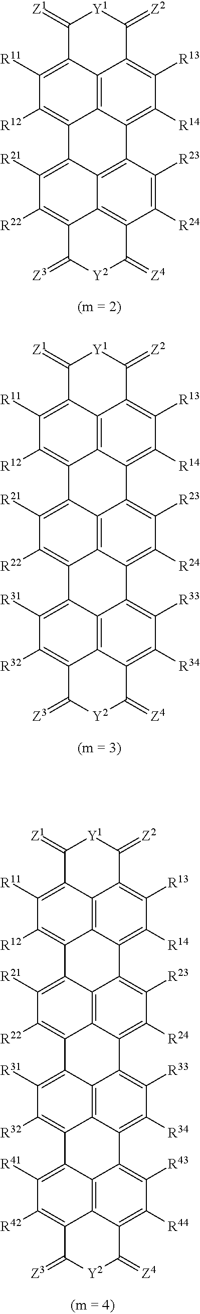

in which
the Rⁿ¹, Rⁿ², Rⁿ³ and Rⁿ⁴ radicals, where n=1 to 4, may each independently be hydrogen, halogen or groups other than halogen,
Y¹ is O or NR^{a} where R^{a} is hydrogen or an organyl radical,
Y² is O or NR^{b} where R^{b} is hydrogen or an organyl radical,
Z¹, Z², Z³ and Z⁴ are each O,
where, in the case that Y¹ is NR^{a}, one of the Z¹ and Z² radicals may also be NR^{c}, where the R^{a} and R^{c} radicals together are a bridging group having from 2 to 5 atoms between the flanking bonds, and
where, in the case that Y² is NR^{b}, one of the Z³ and Z⁴ radicals may also be NR^{d}, where the R^{b} and R^{d} radicals together are a bridging group having from 2 to 5 atoms between the flanking bonds.

Suitable rylenes are described, for example, in WO2007/074137, WO2007/093643 and WO2007/116001 (PCT/EP2007/053330), which are hereby incorporated by reference.

Also suitable are the following donor semiconductor materials, which can be used, for example, in a tandem cell as described below, in a further subcell instead of DBP:

phthalocyanines which are unhalogenated or halogenated. These include metal-free phthalocyanines or phthalocyanines comprising divalent metals or metal atom-containing groups, especially those of titanyloxy, vanadyloxy, iron, copper, zinc, chloroaluminum, etc. Suitable phthalocyanines are especially copper phthalocyanine, zinc phthalocyanine, chloroaluminum phthalocyanine and metal-free phthalocyanine. In a specific embodiment, a halogenated phthalocyanine is used. These include:
2,6,10,14-tetrafluorophthalocyanines, e.g. chloroaluminum-2,6,10,14-tetrafluorophthalocyanine, copper 2,6,10,14-tetrafluorophthalocyanine and zinc 2,6,10,14-tetrafluorophthalocyanine;
1,5,9,13-tetrafluorophthalocyanines, e.g. chloroaluminum-1,5,9,13-tetrafluorophthalocyanine, copper 1,5,9,13-tetrafluorophthalocyanines and zinc 1,5,9,13-tetrafluorophthalocyanines;
2,3,6,7,10,11,14,15-octafluorophthalocyanine, e.g. chloroaluminum 2,3,6,7,10,11,14,15-octafluorophthalocyanine, copper 2,3,6,7,10,11,14,15-octafluorophthalocyanine and zinc 2,3,6,7,10,11,14,15-octafluorophthalocyanine;
porphyrins, for example 5,10,15,20-tetra(3-pyridyl)porphyrin (TpyP), or else tetrabenzoporphyrins, for example metal-free tetrabenzoporphyrin, copper tetrabenzo-porphyrin or zinc tetrabenzoporphyrin. Especially preferred are tetrabenzoporphyrins which, like the dibenzotetraphenylperiflanthene compound used in accordance with the invention, are processed from solution as soluble precursors and converted to the pigmentary photoactive component on the substrate by thermolysis.

Acenes, such as anthracene, tetracene, pentacene, each of which may be unsubstituted or substituted. Substituted acenes comprise preferably at least one substituent which is selected from electron-donating substituents (e.g. alkyl, alkoxy, ester, carboxylate or thioalkoxy), electron-withdrawing substituents (e.g. halogen, nitro or cyano) and combinations thereof. These include 2,9-dialkylpentacenes and 2,10-dialkylpentacenes, 2,10-dialkoxypentacenes, 1,4,8,11-tetraalkoxypentacenes and rubrene (5,6,11,12-tetraphenylnaphthacene). Suitable substituted pentacenes are described in US 2003/0100779 and U.S. Pat. No. 6,864,396, which are hereby incorporated by reference. A preferred acene is rubrene.

Liquid-crystalline (LC) materials, for example coronenes, such as hexabenzocoronene (HBC-PhC₁₂), coronenediimides, or triphenylenes such as 2,3,6,7,10,11-hexahexylthiotriphenylene (HTT₆), 2,3,6,7,10,11-hexakis(4-n-nonylphenyl)triphenylene (PTP₉) or 2,3,6,7,10,11-hexakis(undecyloxy)triphenylene (HAT₁₁). Particular preference is given to liquid-crystalline materials which are discotic.

Thiophenes, oligothiophenes and substituted derivatives thereof; suitable oligothiophenes are quaterthiophenes, quinquethiophenes, sexithiophenes, α,ω-di(C₁-C₈)alkyloligothiophenes such as α,ω-dihexylquaterthiophenes, α,ω-dihexylquinquethiophenes and α,ω-dihexylsexithiophenes, poly(alkylthiophenes) such as poly(3-hexylthiophene), bis(dithienothiophenes), anthradithiophenes and dialkylanthradithiophenes such as dihexylanthradithiophene, phenylene-thiophene (P-T) oligomers and derivatives thereof, especially α,ω-alkyl-substituted phenylene-thiophene oligomers.

Also suitable are compounds of the α,α′-bis(2,2-dicyanovinyl)quinquethiophene (DCV5T) type, 3-(4-octylphenyl)-2,2′-bithiophene (PTOPT), poly(3-(4′-(1,4,7-trioxaoctyl)phenyl)thiophene (PEOPT), poly(3-(2′-methoxy-5′-octylphenyl)thiophene)) (POMeOPT), poly(3-octylthiophene) (P₃OT), poly(pyridopyrazinevinylene)-polythiophene blends such as EHH-PpyPz, PTPTB copolymers, BBL, F₈BT, PFMO; see Brabec C., Adv. Mater., 2996, 18, 2884, (PCPDTBT) poly[2,6-(4,4-bis(2-ethylhexyl)-4H-cyclopenta[2,1-b;3,4-b′]-dithiophene)-4,7-(2,1,3-benzothiadiazole)].

Paraphenylenevinylene and paraphenylenevinylene-comprising oligomers or polymers, for example polyparaphenylenevinylene, MEH-PPV (poly(2-methoxy-5-(2′-ethylhexyloxy)-1,4-phenylenevinylene)), MDMO-PPV (poly(2-methoxy-5-(3′,7′-dimethyloctyloxy)-1,4-phenylenevinylene)), PPV, CN-PPV (with various alkoxy derivatives).

Phenyleneethynylene/phenylenevinylene hybrid polymers (PPE-PPV).

Polyfluorenes and alternating polyfluorene copolymers, for example with 4,7-dithien-2′-yl-2,1,3-benzothiadiazole. Also suitable are poly(9,9′-dioctylfluorene-co-benzothiadiazole) (F₈BT), poly(9,9′-dioctylfluorene-co-bis(N,N′-(4-butylphenyl))-bis(N,N′-phenyl)-1,4-phenylenediamine (PFB).

Polycarbazoles, i.e. carbazole-comprising oligomers and polymers.

Polyanilines, i.e. aniline-comprising oligomers and polymers.

Triarylamines, polytriarylamines, polycyclopentadienes, polypyrroles, polyfurans, polysiloles, polyphospholes, TPD, CBP, spiro-MeOTAD.

Particular preference is given to using, in the inventive organic solar cells, DBP and at least one fullerene or fullerene derivative in the photoactive layer. In a particularly preferred embodiment, the semiconductor mixture used in the photoactive layer consists of DBP and C₆₀.

The content of dibenzotetraphenylperiflanthene in the photoactive layer is preferably from 10 to 90% by weight, more preferably from 25 to 75% by weight, based on the total weight of the semiconductor material (p- and n-semiconductor) in the photoactive layer.

The photoactive layer is configured such that it is sufficiently thick to bring about a maximum light absorption, but thin enough to efficiently extract the charge carriers generated. The thickness of the layer is preferably within a range from 5 to 200 nm, more preferably from 10 to 80 nm.

In addition to the photoactive layer, the organic solar cell may have one or more further layers.

These include, for example,
layers with hole-conducting properties (hole transport layer, HTL),
layers with electron-conducting properties (ETL, electron transport layer),
exciton-blocking (and optionally hole-blocking) layers (EBL).

Suitable layers with hole-conducting properties preferably comprise at least one material with a low ionization energy based on vacuum level, i.e. the layer with hole-conducting properties has a lower ionization energy and a lower electron affinity, based on vacuum level, than the layer with electron-conducting properties. The materials may be organic or inorganic materials. Organic materials suitable for use in a layer with hole-conducting properties are preferably selected from poly(3,4-ethylenedioxythiophene) poly(styrenesulfonate) (PEDOT-PSS), Ir-DPBIC (tris-N,N″-diphenylbenzimidazol-2-ylideneiridium(III)), N,N′-diphenyl-N,N′-bis(3-methylphenyl)-1,1′-diphenyl-4,4′-diamine (α-NPD), 2,2′,7,7′-tetrakis(N,N-di-p-methoxyphenylamine)-9,9′-spirobifluorene (spiro-MeOTAD), etc. and mixtures thereof. The organic materials may, if desired, be doped with a p-dopant which has a LUMO which is in the same region or lower than the HOMO of the hole-conducting material. Suitable dopants are, for example, 2,3,5,6-tetrafluoro-7,7,8,8-tetracyanoquinodimethane (F₄TCNQ), WO₃, MoO₃, etc. Inorganic materials suitable for use in a layer with hole-conducting properties are preferably selected from WO₃, MoO₃, etc.

Where present, the thickness of the layers with hole-conducting properties is preferably within a range from 5 to 200 nm, more preferably from 10 to 100 nm.

Suitable layers with electron-conducting properties comprise preferably at least one material whose LUMO, based on vacuum level, is energetically higher than the LUMO of the material with hole-conducting properties. The materials may be organic or inorganic materials. Organic materials suitable for use in a layer with electron-conducting properties are preferably selected from the aforementioned fullerenes and fullerene derivatives, 2,9-dimethyl-4,7-diphenyl-1,10-phenanthroline (BCP), 4,7-diphenyl-1,10-phenanthroline (Bphen), 1,3-bis[2-(2,2″-bipyridin-6-yl)-1,3,4-oxadiazo-5-yl]benzene (BPY-OXD), etc. The organic materials may, if desired, be doped with an n-dopant which has a HOMO which is in the same region or lower than the LUMO of the electron-conducting material. Suitable dopants are, for example, Cs₂CO₃, Pyronin B (PyB), Rhodamine B, cobaltocene, etc. Inorganic materials suitable for use in a layer with electron-conducting properties are preferably selected from ZnO, etc. The layer with electron-conducting properties more preferably comprises C₆₀.

Where present, the thickness of the layers with electron-conducting properties is preferably within a range from 5 to 200 nm, more preferably from 10 to 100 nm.

Suitable exciton- and hole-blocking layers are described, for example, in U.S. Pat. No. 6,451,415. Suitable materials for exciton blocker layers are, for example, 2,9-dimethyl-4,7-diphenyl-1,10-phenanthroline (BCP), 4,7-diphenyl-1,10-phenanthroline (Bphen), 1,3-bis[2-(2,2-bipyridin-6-yl)-1,3,4-oxadiazo-5-yl]benzene (BPY-OXD), polyethylenedioxythiophene (PEDOT), etc. Preference is given to using a material which is simultaneously very suitable for electron transport. Preference is given to BCP, Bphen and BPY-OXD.

Where present, the thickness of the layers with exciton-blocking properties is preferably within a range from 1 to 50 nm, more preferably from 2 to 20 nm.

According to the invention, the heterojunction is configured as a bulk heterojunction or interpenetrating donor-acceptor network (cf., for example, C. J. Brabec, N. S. Sariciftci, J. C. Hummelen, Adv. Funct. Mater., 11 (1), 15 (2001).). The inventive solar cells thus obtained surprisingly have advantageous properties compared to solar cells in which the heterojunction has a flat (smooth) configuration. For the structure of solar cells with flat heterojunctions, reference is made, for example, to C. W. Tang, Appl. Phys. Lett., 48 (2), 183-185 (1986) or N. Karl, A. Bauer, J. Holzäpfel, J. Marktanner, M. Möbus, F. Stölzle, Mol. Cryst. Liq. Cryst., 252, 243-258 (1994).

In a preferred embodiment, the photoactive donor-acceptor transitions in the form of a bulk heterojunction are produced by a gas phase deposition process (Physical Vapor Deposition, PVD). Suitable methods are described, for example, in US 2005/0227406, which is hereby incorporated by reference. To this end, dibenzotetraphenylperiflanthene and at least one electron acceptor material can be subjected to a gas phase deposition for the purposes of cosublimation. PVD methods are carried out under high-vacuum conditions and comprise the following steps: evaporation, transport, deposition.

The deposition is effected preferably at a pressure in the range from about 10⁻⁵ to 10⁻⁷ mbar.

The deposition rate is preferably within a range from about 0.01 to 10 nm/s.

The temperature of the substrate in the deposition is preferably within a range from about −100 to 300° C., more preferably from −50 to 250° C. The deposition can be effected under an inert atmosphere, for example under nitrogen, argon or helium.

The remaining layers which form the solar cell can be produced by customary methods known to those skilled in the art. These include vapor deposition under reduced pressure or in an inert gas atmosphere, laser ablation or solution or dispersion processing methods such as spin-coating, knife-coating, casting methods, spray application, dip-coating or printing (e.g. inkjet, flexographic, offset, gravure; intaglio, nanoimprinting). Preference is given to producing the entire solar cell by a gas phase deposition process.

The photoactive layer (mixed layer) can be subjected to a thermal treatment directly after its production or after production of further layers which form the solar cell. Such a heat treatment can in many cases improve the morphology of the photoactive layer further. The temperature is preferably within a range from about 60° C. to 300° C. The treatment time is preferably within a range from 1 minute to 3 hours. Supplementarily or alternatively to a thermal treatment, the photoactive layer (mixed layer) can be subjected to a treatment with a solvent-containing gas directly after its production or after production of further layers which form the solar cell. In a suitable embodiment, saturated solvent vapors in air are used at ambient temperature. Suitable solvents are toluene, xylene, chloroform, N-methylpyrrolidone, dimethylformamide, ethyl acetate, chlorobenzene, dichloromethane and mixtures thereof. The treatment time is preferably within a range from 1 minute to 3 hours.

The inventive solar cells may be present in the form of a single cell with normal structure. In a specific embodiment, such a cell has the following layer structure:
an at least partially light-transparent substrate,
a first electrode (front electrode, anode),
a hole transport layer,
a mixed layer composed of DBP and at least one electron acceptor in the form of a bulk heterojunction,
an electron transport layer,
an exciton blocker/electron transport layer,
a second electrode (back electrode, cathode).

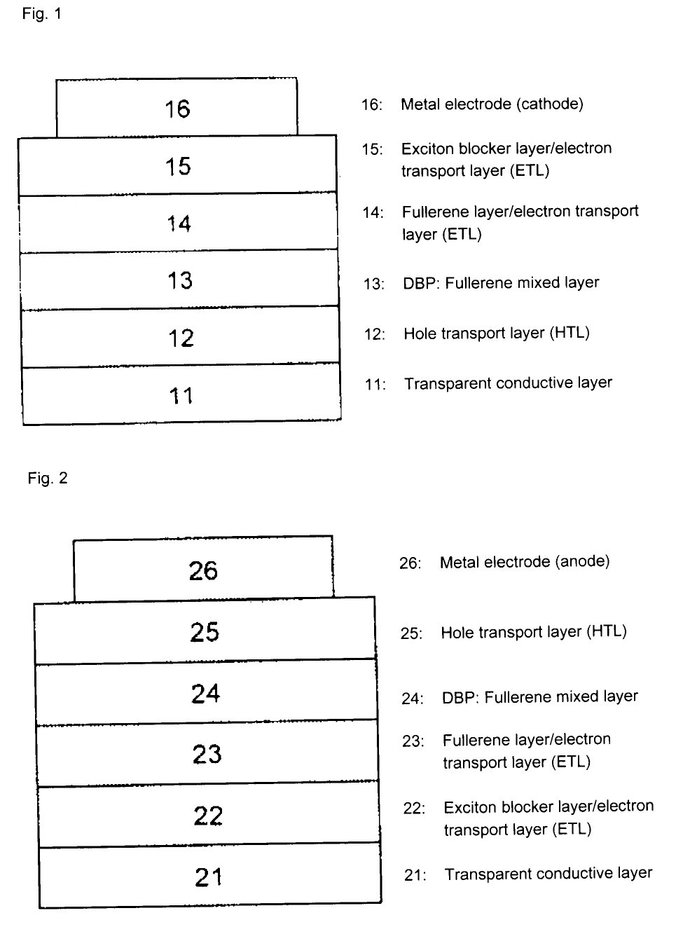

FIG. 1 shows an inventive solar cell with normal structure.

The inventive solar cells may also be present as a single cell with inverse structure. In a specific embodiment, such a cell has the following layer structure:
an at least partially light-transparent substrate,
a first electrode (front electrode, cathode),
an exciton blocker/electron transport layer,
an electron transport layer,
a mixed layer composed of DBP and at least one electron acceptor in the form of a bulk heterojunction,
a hole transport layer,
a second electrode (back electrode, anode).

FIG. 2 shows an inventive solar cell with inverse structure.

The inventive solar cells may also be configured as a tandem cell. The basic structure of a tandem cell is described, for example, by P. Peumans, A. Yakimov, S. R. Forrest in J. Appl. Phys, 93 (7), 3693-3723 (2003) and U.S. Pat. No. 4,461,922, U.S. Pat. No. 6,198,091 and U.S. Pat. No. 6,198,092.

A tandem cell consists of two or more than two (e.g. 3, 4, 5, etc.) subcells. A single subcell, some of the subcells or all subcells may have photoactive donor-acceptor transitions in the form of a bulk heterojunction based on dibenzotetraphenylperiflanthene. Preferably, at least one of the subcells comprises DBP and at least one fullerene or fullerene derivative. More preferably, the semiconductor mixture used in the photoactive layer of at least one subcell consists of DBP and C₆₀.

The subcells which form the tandem cell may be connected in parallel or in series. The subcells which form the tandem cell are preferably connected in series. Between the individual subcells, there is preferably an additional recombination layer in each case. The individual subcells have the same polarity, i.e. generally either only cells with normal structure or only cells with inverse structure are combined with one another.

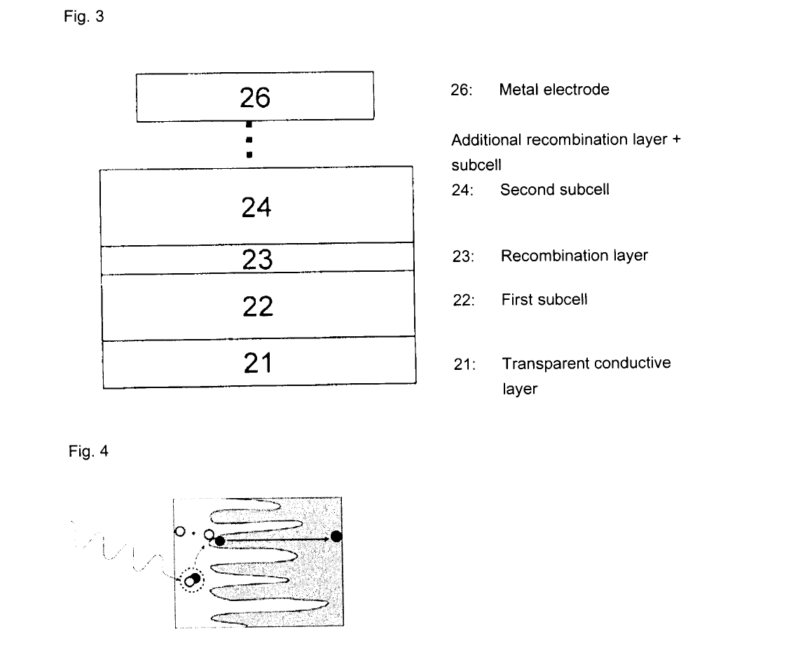

FIG. 3 shows the basic structure of an inventive tandem cell. Layer 21 is a transparent conductive layer. Suitable materials are those specified above for the individual cells.

Layers 22 and 24 constitute subcells. A “subcell” refers to a cell as defined above without a cathode and anode. The subcells may, for example, either all have DBP-C60 bulk heterojunctions or other combinations of semiconductor materials, for example C60 with Zn phthalocyanine, C60 with oligothiophene (such as DCV5T). In addition, individual subcells may also be configured as dye-sensitized solar cells or polymer cells. In all cases, preference is given to a combination of materials which exploit different regions of the spectrum of the incident radiation, for example of natural sunlight. For example, DBP-C60 absorbs in particular in the range from 400 nm to 600 nm. Zn phthalocyanine-C60 cells absorb in particular in the range from 600 nm to 800 nm. A tandem cell composed of a combination of these subcells should thus absorb radiation in the range from 400 nm to 800 nm. A suitable combination of subcells thus allows the spectral range utilized to be extended. For optimal performance properties, optical interference should be considered. Thus, subcells which absorb at shorter wavelengths should be arranged closer to the metal top contact than subcells with longer-wave absorption.

It is likewise possible that a tandem cell has at least one subcell in which the photoactive donor-acceptor transition is present in the form of a flat heterojunction. In that case, the aforementioned semiconductor materials can be used, which may additionally also be doped. Suitable dopants are, for example, Pyronin B and rhodamine derivatives.

Layer 23 is a recombination layer. Recombination layers enable recombination of the charge carriers from a subcell with those of an adjacent subcell. Small metal clusters are suitable, such as Ag, Au or combinations of highly n- and p-doped layers. In the case of metal clusters, the layer thickness is preferably within a range of 0.5-5 nm. In the case of highly n- and p-doped layers, the layer thickness is preferably within a range of 5-40 nm. The recombination layer generally connects the electron transport layer of a subcell to the hole transport layer of an adjacent subcell. In this way, further cells can be combined to give the tandem cell.

Layer 26 is the top electrode. The material depends on the polarity of the subcells. For subcells with normal structure, preference is given to using metals with a low work function, such as Ag, Al, Mg, Ca, etc. For subcells with inverse structure, preference is given to using metals with a high work function, such as Au or Pt, or PEDOT-PSS.

In the case of series-connected subcells, the total voltage corresponds to the sum of the individual voltages of all subcells. The total current level, in contrast, is limited by the lowest current level of a subcell. For this reason, the thickness of each subcell should be optimized such that all subcells have essentially the same current level.

The invention is illustrated in detail by the nonlimiting examples which follow.

### EXAMPLES

### Example 1

### Preparation of a Mixture of

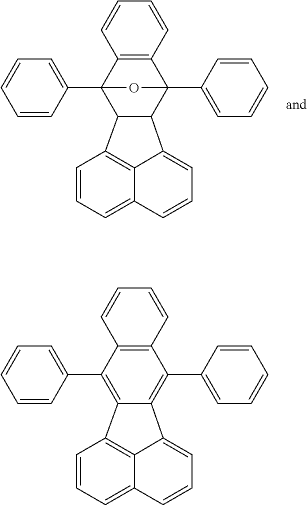

50 ml of xylene, 5.0 g (18.5 mmol) of 1,3-diphenylisobenzofuran and 4.0 g (22 mmol) of acenaphthylene (80% purity) were heated at reflux for 7 hours. After the reaction mixture had been cooled to room temperature, approx. 40 ml of ethanol were added and the resulting precipitate was filtered off. This afforded 6.8 g (87%) of a reaction product which, according to ¹³C NMR spectroscopy, is present as a 1:1 mixture of the above-described compounds.

### Example 2

### Diphenylfluoranthene

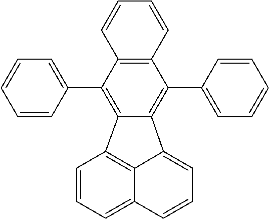

6.0 g (14.2 mmol) of the reaction product from example 1 were heated to reflux temperature in a mixture of 40 ml of acetic acid and 4.1 ml of 48% hydrobromic acid for two hours. The resulting residue was filtered off and washed with ethanol. This afforded 5.7 g (98%) of a strongly fluorescing compound (melting point: 272° C.).

### Example 3

### Dibenzotetraphenylperiflanthene

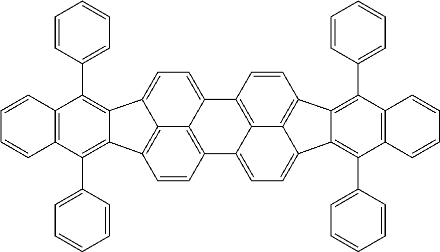

A mixture of 60 ml of trifluoroacetic acid, 5.0 g of diphenylfluoranthene (12 mmol) and 7.6 g (65 mmol) of cobalt trifluoride was heated to reflux temperature (72° C.) for 20 hours. The reaction mixture was added to 400 ml of water and the product was extracted by extracting three times with 400 ml of dichloromethane each time. The combined organic phases were washed three times with 400 ml of water each time and dried over MgSO₄, and the solvent was removed under reduced pressure. The residue was purified by chromatography on silica gel with a gradient of petroleum ether and toluene and subsequent crystallization from the corresponding solvent mixture. This afforded 0.92 g (18%) of a high-purity fraction. The remaining slightly contaminated fractions gave rise to a further 1.14 g (22%).

The high-purity crystalline fraction is subjected to a three-zone sublimation to produce solar cells.

### Sublimation of DBP:

DBP was purified by three-zone sublimation at 2-3×10⁻⁶ mbar, the first zone having been at 450° C. The product sublimed at 250±50° C. was used. From an 821 mg loading, 553 mg (67%) of sublimed product were obtained after sublimation for 48 hours.

### Materials:

DBP: purified (once) by three-zone sublimation, as described above.
C60: from Alfa Aesar, purity (purity +99.92%, sublimed), used without further purification.
Bphen: from Alfa Aesar, used without further purification.

### Substrate:

ITO was sputtered onto the glass substrate. The thickness of the ITO film was 140 nm, the specific resistance (resistivity) 200 μΩcm and the RMS (root mean square) roughness was less than 5 nm. Before the deposition of the organic material, the substrate was “ozonized” by UV irradiation for 20 minutes (UV ozone cleaning).

### Production of the Cells:

Bilayer cells and bulk heterojunction cells (BHJ cells) were produced under high vacuum (pressure<10⁻⁶ mbar). In the bilayer cell, the donor-acceptor transition has a flat (smooth) configuration. In contrast, an interpenetrating donor-acceptor network is present in the bulk heterojunction cell.

To produce the bilayer cell (ITO/DBP/C60/Bphen/Ag), DBP and C60 were applied successively by vapor deposition to the ITO substrate. The deposition rate for the two layers was in each case 0.2 nm/sec. The deposition temperatures were 410° C. and 400° C. respectively. Subsequently, Bphen and then 100 nm of Ag as the top contact were applied by vapor deposition. The arrangement had an area of 0.03 cm².

To produce the BHJ cell (ITO/DBP:C60(1:1)/C60/Bphen/Ag), DBP and C60 were deposited onto the ITO substrate by coevaporation at the same rate (0.1 nm/sec), such that the DBP/C60 volume ratio in the mixed layer was 1:1. The Bphen and Ag layers were deposited as described for the bilayer cell.

### Analysis:

The solar simulator used was an AM 1.5 simulator from Solar Light, USA, with a xenon lamp (model 16S-150 V3). The UV region below 415 nm was filtered and current-voltage measurements were carried out under ambient conditions. The intensity of the solar simulator was calibrated with a monocrystalline FZ (float zone) silicon solar cell (Fraunhofer ISE). According to calculation, the mismatch factor was approximately 1.0.

### Results:

Bilayer cell

| DBP | C60 | Bphen | V_{OC} | I_{SC} | | η |
|---|---|---|---|---|---|---|
| [nm] | [nm] | [nm] | [mV] | [mA/cm²] | FF | [%] |
| 20 | 40 | 6 | 917 | −5.48 | 51.2 | 2.58 |
| 30 | 40 | 6 | 920 | −5.33 | 39.8 | 1.95 |

BHJ cell

| DBP:C60 | C60 | Bphen | V_{OC} | I_{SC} | | η |
|---|---|---|---|---|---|---|
| [nm] | [nm] | [nm] | [mV] | [mA/cm²] | FF | [%] |
| 20 | 20 | 6 | 832 | −11.10 | 47.8 | 4.37 |
| 30 | 20 | 6 | 745 | −10.58 | 32.7 | 2.58 |
| 40 | 10 | 6 | 860 | −12.60 | 46.0 | 4.98 |

1. A method for manufacturing an organic solar cell, comprising:
adding an electron donor material comprising a dibenzotetraphenylperiflanthene represented by formula (I) 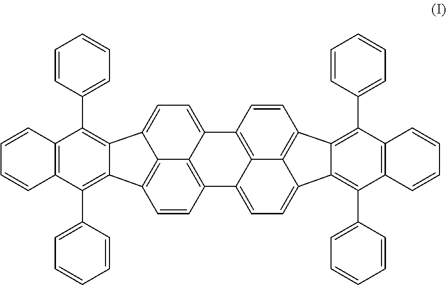
to a photoactive layer present in an organic solar cell, wherein the organic solar cell is in a form of a bulk heterojunction.

2. The method according to claim 1, wherein the organic solar cell further comprises an electron acceptor material which comprises a fullerene compound.

3. The method according to claim 1, wherein the organic solar cell is in a form of a single cell or in the form of a tandem cell.

4. The method according to claim 1, wherein at least one photoactive donor-acceptor transition is produced by a gas phase deposition process.

5. An organic solar cell, comprising:
a photoactive layer;
wherein the photoactive layer comprises an electron donor material which comprises a dibenzotetraphenylperiflanthene and
at least one photoactive donor-acceptor transition in the form of a bulk heterojunction is present in an organic solar cell.

6. The solar cell according to claim 5, wherein the solar cell is in a form of a single cell or in the form of a tandem cell.
